(19) United States
(12) Patent Application Publication
(10) Pub. No.: US 2025/0231497 A1
(43) Pub. Date: Jul. 17, 2025

(54) PATTERN MEASUREMENT METHOD AND PATTERN MEASUREMENT APPARATUS

(71) Applicant: Samsung Electronics Co., Ltd., Suwon-si (KR)

(72) Inventors: Ji Yong KIM, Suwon-si (KR); Ki Seok KWAK, Suwon-si (KR); Seoung-Bum JUNG, Suwon-si (KR)

(21) Appl. No.: 18/797,875

(22) Filed: Aug. 8, 2024

(30) Foreign Application Priority Data
Jan. 17, 2024 (KR) 10-2024-0007370

(51) Int. Cl. G03F 7/00

(52) U.S. Cl. CPC G03F 7/70666; G03F 7/706851

(57) ABSTRACT

A pattern measurement method includes forming a first pattern having a first size and a first brightness in a the first die area, forming a second pattern having a second size equal to the first size and a second brightness different from the first brightness in the first die area, obtaining a (1-1)-th measured size and a (1-1)-th measured brightness using a first measurement apparatus, and obtaining a (1-2)-th measured size and a (1-2)-th measured brightness using the first measurement apparatus, obtaining a (2-1)-th measured size and a (2-1)-th measured brightness using a second measurement apparatus, and obtaining a (2-2)-th measured size and a (2-2)-th measured brightness using the second measurement apparatus, and calibrating the first measurement apparatus and the second measurement apparatus based on first size correction data and first brightness correction data determined using the measured sizes and brightnesses.

### CROSS-REFERENCE TO RELATED APPLICATION

This application claims priority from Korean Patent Application No. 10-2024-0007370 filed on Jan. 17, 2024 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a pattern measurement method and a pattern measurement apparatus.

### Description of Related Art

A measurement apparatus radiates light to a wafer surface using a lamp, and recognizes data about reflected light using a camera, and processes the data to identify positions of patterns formed on the wafer. In this regard, the ability of the measurement apparatus to recognize the same object multiple times may vary depending on variation in an intensity of the light emitted from the lamp through the camera.

As a result, although two objects may be perceived as the same object by humans, the two objects may be perceived as different objects by the camera. In particular, the brightness of the object may vary each time it is measured depending on a measurement environment or apparatus, even when the object is not changed. Various technologies have been secured to correct a difference between brightnesses of a reference measurement apparatus and a target measurement apparatus. However, an older measurement apparatus may have lowered precision due to difficulties in introducing new technology thereto.

### SUMMARY

A technical purpose of the present disclosure is to provide a pattern measurement method with improved measurement accuracy.

Another technical purpose of the present disclosure is to provide a pattern measurement apparatus with improved measurement accuracy.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

According to some aspects of the present disclosure, a pattern measurement method includes: defining a first die area and a second die area on a wafer; forming a first pattern having a predetermined first size and a predetermined first brightness in the first die area; forming a second pattern having a predetermined second size equal to the predetermined first size and a predetermined second brightness different from the predetermined first brightness in the first die area; measuring the predetermined first size and the predetermined first brightness of the first pattern using a first measurement apparatus and obtaining a (1-1)-th measured size and a (1-1)-th measured brightness, respectively, from a measuring result using the first measurement apparatus, and measuring the predetermined second size and the predetermined second brightness of the second pattern using the first measurement apparatus and obtaining a (1-2)-th measured size and a (1-2)-th measured brightness, respectively, from a measuring result using the first measurement apparatus; measuring the predetermined first size and the predetermined first brightness of the first pattern using a second measurement apparatus different from the first measurement apparatus, and obtaining a (2-1)-th measured size and a (2-1)-th measured brightness, respectively, from a measuring result using the second measurement apparatus, and measuring the predetermined second size and the predetermined second brightness of the second pattern using the second measurement apparatus and obtaining a (2-2)-th measured size and a (2-2)-th measured brightness, respectively, from a measuring result using the second measurement apparatus; defining a difference between the predetermined first size and the (1-1)-th measured size as (1-1)-th size error data; defining a difference between the predetermined first size and the (2-1)-th measured size as (2-1)-th size error data; defining a difference between an intensity of the predetermined first brightness and an intensity of the (1-1)-th measured brightness as (1-1)-th brightness error data; defining a difference between the intensity of the predetermined first brightness and an intensity of the (2-1)-th measured brightness as (2-1)-th brightness error data, generating first size correction data as an average of the (1-1)-th size error data and the (2-1)-th size error data; generating first brightness correction data as an average of the (1-1)-th brightness error data and the (2-1)-th brightness error data; and calibrating the first measurement apparatus and the second measurement apparatus based on the first size correction data and the first brightness correction data.

According to some aspects of the present disclosure, a pattern measurement method includes: fabricating a pattern measurement target; measuring the pattern measurement target using a first measurement apparatus, and measuring the pattern measurement target using a second measurement apparatus different from the first measurement apparatus, and generating size correction data and brightness correction data based on a measuring result using the first measurement apparatus, and based on a measuring result using the second measurement apparatus; and calibrating the first measurement apparatus and the second measurement apparatus based on the size correction data and the brightness correction data, wherein the fabricating the pattern measurement target includes: defining a first die area, a second die area, and a third die area on a wafer; forming a first pattern group including a first pattern and a second pattern in the first die area, wherein the first pattern has a predetermined first size and a predetermined first brightness, and the second pattern has a predetermined second size equal to the predetermined first size and a predetermined second brightness different from the predetermined first brightness; forming a second pattern group including a third pattern and a fourth pattern in the second die area, wherein the third pattern has a predetermined third size different from the predetermined first size and a predetermined third brightness and the fourth pattern has a predetermined fourth size equal to the predetermined third size, and a predetermined fourth brightness different from the predetermined third brightness; and forming a third pattern group including a fifth pattern and a sixth pattern in the third die area, wherein the fifth pattern has a predetermined fifth size different from each of the predetermined first and third sizes, and a predetermined fifth brightness, and the sixth pattern has a predetermined sixth size equal to the predetermined fifth size, and a predetermined sixth brightness different from the predetermined fifth brightness, wherein the measuring the pattern measurement target using the first measurement apparatus includes measuring a size and a brightness of each of the patterns of each of the first to third pattern groups using the first measurement apparatus, wherein the measuring the pattern measurement target using the second measurement apparatus includes measuring a size and a brightness of each of the patterns of each of the first to third pattern groups using the second measurement apparatus, wherein the size correction data is generated based on a difference between the measured size of each of the patterns of each of the first to third pattern groups and the predetermined size of each of the patterns of each of the first to third pattern groups, and wherein the brightness correction data is generated based on a difference between the measured brightness of each of the patterns of each of the first to third pattern groups and the predetermined brightness of each of the patterns of each of the first to third pattern groups.

According to some aspects of the present disclosure, a pattern measurement apparatus includes: a stage onto which a pattern measurement target is loaded; an imaging unit installed on top of the pattern measurement target and configured to image the pattern measurement target; a controller configured to control the imaging unit, wherein the pattern measurement target includes: a wafer including a first die area and a second die area; a first pattern on the first die area and having a predetermined first size and a predetermined first brightness; and a second pattern on the first die area and having a predetermined second size equal to the predetermined first size, and a predetermined second brightness different from the predetermined first brightness, wherein the imaging unit is configured to: image the first pattern and acquire a first measured size and a first measured brightness of the first pattern; and image the second pattern and acquire a second measured size and a second measured brightness of the second pattern, wherein the controller is configured to: determine a first difference between the predetermined first size and the first measured size; determine a second difference between the predetermined second size and the second measured size; determine a third difference between an intensity of the predetermined first brightness and an intensity of the first measured brightness; and determine a fourth difference between an intensity of the predetermined second brightness and an intensity of the second measured brightness; and calibrate the pattern measurement apparatus based on the determined first to fourth differences.

### BRIEF DESCRIPTION OF DRAWINGS

The above and other aspects and features of the present disclosure will become more apparent by describing in detail illustrative embodiments thereof with reference to the attached drawings, in which:

FIG. 1 is an example plan view for illustrating a pattern measurement target according to some embodiments.

FIG. 2 is a diagram for illustrating a first die area in FIG. 1.

FIG. 3 is a diagram for illustrating a second die area in FIG. 1.

FIG. 4 is a diagram for illustrating a third die area in FIG. 1.

FIG. 5 is a diagram for illustrating a fourth die area in FIG. 1.

FIG. 6 is an example diagram for illustrating a measurement apparatus according to some embodiments of the present disclosure.

FIG. 7 is an example flow chart for illustrating a pattern measurement method according to some embodiments of the present disclosure.

FIG. 8 is an example flowchart for illustrating a method for manufacturing the pattern measurement target in FIG. 7.

FIGS. 9 to 12 are diagrams of intermediate structures corresponding to intermediate steps of the pattern measurement method according to some embodiments of the present disclosure.

### DETAILED DESCRIPTIONS

In this specification, although terms such as “first,” “second,” “upper,” and “lower” are used to describe various elements or components, these elements or components are not limited by these terms. These terms are merely used to distinguish one element or component from another. Therefore, a first element or component mentioned below may be a second element or component within the technical spirit of the present disclosure. Similarly, a lower element or component mentioned below may be an upper element or component within the technical spirit of the present disclosure.

A pattern measurement apparatus according to some embodiments may have a feature of measuring a constant size and brightness of patterns formed on a pattern measurement target within different measurement apparatuses. The pattern measurement apparatus according to some embodiments may measure the size and the brightness of the patterns, and compare an actual size and the measured size of the patterns, and compare an actual brightness and the measured brightness of the patterns, and obtain a corrected value based on the comparing results and apply the corrected value back to the measurement apparatus. Accordingly, actual defects formed on the wafer may be accurately detected. Before describing the above feature, the pattern measurement target is first described.

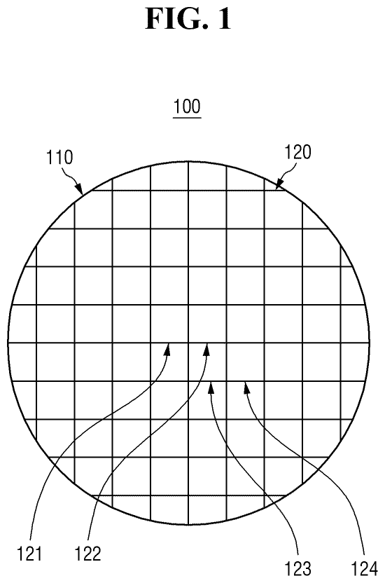

First, referring to FIGS. 1 to 5, the pattern measurement target according to some embodiments is described.

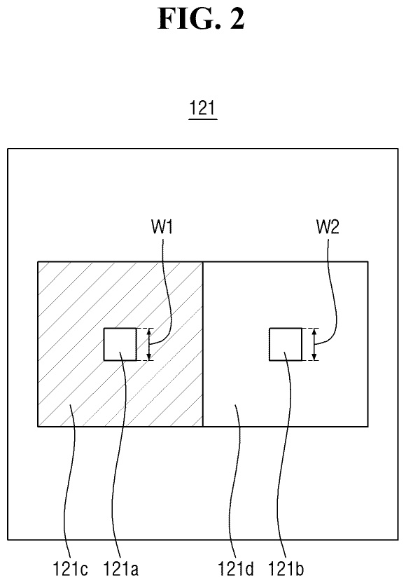

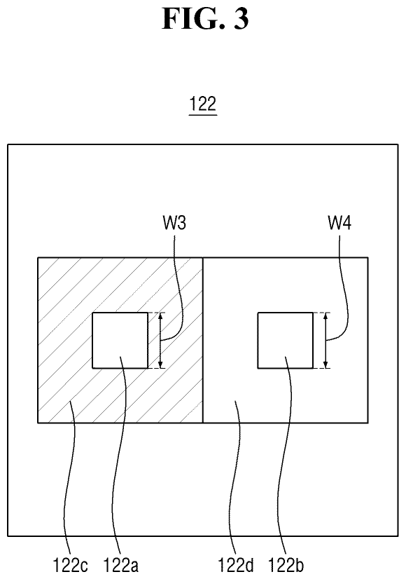

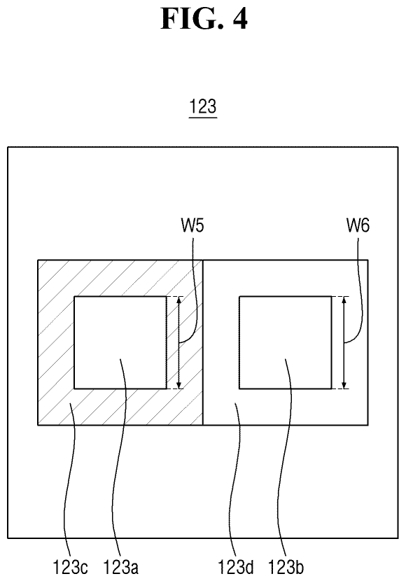

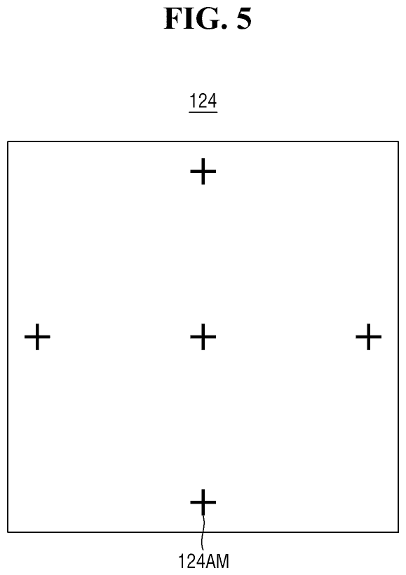

FIG. 1 is an example plan view for illustrating a pattern measurement target according to some embodiments. FIG. 2 is a diagram for illustrating a first die area 121 in FIG. 1. FIG. 3 is a diagram for illustrating a second die area 122 in FIG. 1. FIG. 4 is a diagram for illustrating a third die area 123 in FIG. 1. FIG. 5 is a diagram for illustrating a fourth die area 124 in FIG. 1.

Referring to FIGS. 1 to 5, a pattern measurement target 100 may include a wafer 110 and a plurality of die areas 120.

The wafer 110 may include a silicon wafer. Alternatively, the wafer 110 may include a material other than silicon. For example, the wafer 110 may include, but is not limited to, silicon germanium, silicon germanium on insulator (SGOI), indium antimonide, lead telluride compound, indium arsenide, indium phosphide, gallium arsenide, or gallium antimonide. Hereinafter, an example in which the wafer 110 includes silicon is described.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

The plurality of die areas 120 may be defined on a surface of the wafer 110. In FIG. 1, the plurality of die areas 120 may be defined by a plurality of lines extending in a column direction and a plurality of lines extending in a row direction. Area sizes of the plurality of die areas 120 may be substantially equal to each other. However, the technical idea of the present disclosure is not limited thereto.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

A plurality of patterns may be formed on the plurality of die areas 120. For example, a pattern group including two patterns may be formed on each of the die areas 120. The pattern group may include two adjacent patterns. The two patterns may have the same size but different brightnesses (e.g., gray levels).

For example, the plurality of die areas 120 may include a first die area 121, a second die area 122, a third die area 123, and a fourth die area 124.

In FIG. 2, the first die area 121 may include a first pattern 121a and a second pattern 121b. The first pattern 121a and the second pattern 121b may constitute a first pattern group. The first pattern 121a and the second pattern 121b may be arranged adjacent to each other in the row direction. The first pattern 121a and the second pattern 121b may be spaced from each other.

The first pattern 121a may be disposed within a first background 121c. The second pattern 121b may be disposed within a second background 121d. In some embodiments, brightnesses (e.g., predetermined brightnesses) of the first background 121c and the second background 121d may be different from each other. For example, the brightness of the first background 121c may be lower than the brightness of the second background 121d. That is, the first background 121c may be darker than the second background 121d. More specifically, the brightness of the first background 121c may be black, and the brightness of the second background 121d may be white.

In some embodiments, each of an intensity of the brightness of the first background 121c and the intensity of the brightness of the second background 121d may be expressed as an integer between 0 and 255. For example, the intensity of the brightness of the first background 121c may be 255, and the intensity of the brightness of the second background 121d may be 0. However, the technical idea of the present disclosure is not limited thereto.

Alternatively, each of the intensity of the brightness of the first background 121c and the intensity of the brightness of the second background 121d may be expressed as an integer between 0 and 510, or may be expressed as an integer between 0 and 1020. In another example, a scheme of expressing the intensity of the brightness may be changed as much as desired depending on a design.

In some embodiments, a first size (e.g., a predetermined first size) of the first pattern 121a and a second size (e.g., a predetermined second size) of the second pattern 121b may be equal to each other. Specifically, the first pattern 121a has a first width W1. The second pattern 121b has a second width W2. The first width W1 and the second width W2 may be equal to each other.

However, in some embodiments, a first brightness (e.g., a predetermined first brightness) of the first pattern 121a may be different from a second brightness (e.g., a predetermined second brightness) of the second pattern 121b. Each of a color of the first pattern 121a and a color of the second pattern 121b may be, for example, gray, but the inventive concept is not limited thereto. The first brightness of the first pattern 121a may be higher than the second brightness of the second pattern 121b. That is, the first pattern 121a may be lighter gray than the second pattern 121b may be while the second pattern 121b may be darker gray than the first pattern 121a may be.

In some embodiments, each of the intensity of the first brightness of the first pattern 121a and the intensity of the second brightness of the second pattern 121b may be expressed as a natural number between 0 and 255. For example, the intensity of the first brightness of the first pattern 121a may be a natural number between 0 and 125, and the intensity of the second brightness of the second pattern 121b may be a natural number between 126 and 255. However, the technical idea of the present disclosure is not limited thereto.

In some embodiments, each of the intensity of the first brightness of the first pattern 121a and the intensity of the second brightness of the second pattern 121b may be expressed as a natural number between 0 and 510, or may be expressed as a natural number between 0 and 1020. In another example, a scheme of expressing the intensity of the brightness may be changed as much as desired depending on a design.

In FIG. 3, the second die area 122 may include a third pattern 122a and a fourth pattern 122b. The third pattern 122a and the fourth pattern 122b may constitute a second pattern group. The third pattern 122a and the fourth pattern 122b may be arranged adjacent to each other in the row direction. The third pattern 122a and the fourth pattern 122b may be spaced apart from each other.

The third pattern 122a may be disposed within a third background 122c. The fourth pattern 122b may be disposed within a fourth background 122d. In some embodiments, brightnesses (e.g., predetermined brightnesses) of the third background 122c and the fourth background 122d may be different from each other. For example, the brightness of the third background 122c may be lower than the brightness of the fourth background 122d. That is, the former may be darker than the latter. More specifically, the brightness of the third background 122c may be black, and the brightness of the fourth background 122d may be white.

In some embodiments, each of an intensity of the brightness of the third background 122c and an intensity of the brightness of the fourth background 122d may be expressed as an integer between 0 and 255. For example, the brightness intensity of the third background 122c may be 255, and the brightness intensity of the fourth background 122d may be 0. That is, the brightness of the third background 122c may be equal to the brightness of the first background 121c, and the brightness of the fourth background 122d may be equal to the brightness of the second background 121d. However, the technical idea of the present disclosure is not limited thereto.

In some embodiments, a third size (e.g., a predetermined third size) of the third pattern 122a and a fourth size (e.g., a predetermined fourth size) of the fourth pattern 122b may be equal to each other. Specifically, the third pattern 122a has a third width W3. The fourth pattern 122b has a fourth width W4. The third width W3 and the fourth width W4 may be equal to each other.

However, in some embodiments, a third brightness (e.g., a predetermined third brightness) of the third pattern 122a may be different from a fourth brightness (e.g., a predetermined fourth brightness) of the fourth pattern 122b. Each of a color of the third pattern 122a and a color of the fourth pattern 122b may be, for example, gray, but the inventive concept is not limited thereto. The third brightness of the third pattern 122a may be higher than the fourth brightness of the fourth pattern 122b. That is, the third pattern 122a may be lighter gray than the fourth pattern 122b may be while the fourth pattern 122b may be darker gray than the third pattern 122a may be.

In some embodiments, each of the intensity of the third brightness of the third pattern 122a and the intensity of the fourth brightness of the fourth pattern 122b may be expressed as a natural number between 0 and 255. For example, the third brightness of the third pattern 122a may be a natural number between 0 and 125, and the intensity of the fourth brightness of the fourth pattern 122b may be a natural number between 126 and 255. However, the technical idea of the present disclosure is not limited thereto.

In some embodiments, the first size of the first pattern 121a is smaller than the third size of the third pattern 122a. Likewise, the second size of the second pattern 121b is smaller than the fourth size of the fourth pattern 122b. That is, the first width W1 is smaller than the third width W3. The second width W2 is smaller than the fourth width W4.

In this regard, a difference between the brightness intensities of the first pattern 121a and the second pattern 121b may be smaller than a difference between the brightness intensities of the third pattern 122a and the fourth pattern 122b. For example, the first pattern 121a may be a darker gray than the third pattern 122a may be, while the second pattern 121b may be a lighter gray than the fourth pattern 122b may be. In other words, when a difference between the intensity of the first brightness and the intensity of the second brightness is A, and a difference between the intensity of the third brightness and the intensity of the fourth brightness is B, then A may be smaller than B. In other words, the larger the sizes of the patterns complementary to each other, the larger a difference between the brightnesses of the patterns complementary to each other.

In FIG. 4, the third die area 123 may include a fifth pattern 123a and a sixth pattern 123b. The fifth pattern 123a and the sixth pattern 123b may constitute a third pattern group. The fifth pattern 123a and the sixth pattern 123b may be arranged adjacent to each other in the row direction. The fifth pattern 123a and the sixth pattern 123b may be spaced apart from each other.

The fifth pattern 123a may be disposed within a fifth background 123c. The sixth pattern 123b may be disposed within a sixth background 123d. In some embodiments, a brightness (e.g., a predetermined brightness) of the fifth background 123c and a brightness (e.g., a predetermined brightness) of the sixth background 123d may be different from each other. For example, the brightness of the fifth background 123c may be lower than the brightness of the sixth background 123d. That is, the former may be darker than the latter. More specifically, the brightness of the fifth background 123c may be black, and the brightness of the sixth background 123d may be white.

In some embodiments, each of an intensity of the brightness of the fifth background 123c and an intensity of the brightness of the sixth background 123d may be expressed as an integer between 0 and 255. For example, the intensity of the brightness of the fifth background 123c may be 255, and the intensity of the brightness of the sixth background 123d may be 0. That is, the brightness of the fifth background 123c may be equal to each of the brightness of the first background 121c and the brightness of the third background 122c, while the brightness of the sixth background 123d may be equal to each of the brightness of the second background 121d and the brightness of the fourth background 122d. However, the technical idea of the present disclosure is not limited thereto.

In some embodiments, a fifth size (e.g., a predetermined fifth size) of the fifth pattern 123a and a sixth size (e.g., a predetermined sixth size) of the sixth pattern 123b may be equal to each other. Specifically, the fifth pattern 123a has a fifth width W5. The sixth pattern 123b has a sixth width W6. The fifth width W5 and the sixth width W6 may be equal to each other.

However, in some embodiments, a fifth brightness (e.g., a predetermined fifth brightness) of the fifth pattern 123a may be different from a sixth brightness (e.g., a predetermined sixth brightness) of the sixth pattern 123b. Each of a color of the fifth pattern 123a and the color of the sixth pattern 123b may be, for example, gray, but the inventive concept is not limited thereto. The fifth brightness of the fifth pattern 123a may be higher than the sixth brightness of the sixth pattern 123b. That is, the former may be brighter than the latter. That is, the fifth pattern 123a may be lighter gray than the sixth pattern 123b may be, while the sixth pattern 123b may be darker gray than the fifth pattern 123a may be.

In some embodiments, each of an intensity of the fifth brightness of the fifth pattern 123a and an intensity of the sixth brightness of the sixth pattern 123b may be expressed as a natural number between 0 and 255. For example, the intensity of the fifth brightness of the fifth pattern 123a may be a natural number between 0 and 125, and the intensity of the sixth brightness of the sixth pattern 123b may be a natural number between 126 and 255. However, the technical idea of the present disclosure is not limited thereto.

In some embodiments, the first size of the first pattern 121a is smaller than the fifth size of the fifth pattern 123a. Likewise, the third size of the third pattern 122a is smaller than the fifth size of the fifth pattern 123a. Moreover, the second size of the second pattern 121b is smaller than the sixth size of the sixth pattern 123b. The fourth size of the fourth pattern 122b is smaller than the sixth size of the sixth pattern 123b. That is, the fifth width W5 is larger than each of the third width W3 and the first width W1. The sixth width W6 is larger than each of the fourth width W4 and the second width W2.

In this regard, the difference between the intensity of the brightness of the first pattern 121a and the second pattern 121b may be smaller than a difference between the intensity of the brightness of the fifth pattern 123a and the sixth pattern 123b. For example, the first pattern 121a may be a darker gray than the fifth pattern 123a may be, while the second pattern 121b may be a lighter gray than the sixth pattern 123b may be. Moreover, the difference between the intensity of the brightness of the third pattern 122a and the fourth pattern 122b may be smaller than the difference between the intensity of the brightness of the fifth pattern 123a and the sixth pattern 123b. For example, the third pattern 122a may be a darker gray than the fifth pattern 123a may be while the fourth pattern 122b may be a lighter gray than the sixth pattern 123b may be.

In other words, when the difference between the intensity of the first brightness and the intensity of the second brightness is A, the difference between the intensity of the third brightness and the intensity of the fourth brightness is B, and the difference between the intensity of the fifth brightness and the intensity of the sixth brightness is C, then A may be smaller than each of B and C, and B may be smaller than C.

Moreover, the intensity of the first brightness is greater than the intensity of the third brightness. The intensity of the third brightness is greater than the intensity of the fifth brightness. The intensity of the second brightness is lower than the intensity of the fourth brightness. The intensity of the fourth brightness is lower than the intensity of the fifth brightness.

In other words, the larger the sizes of the patterns complementary to each other, the larger the difference between the brightnesses of the patterns complementary to each other.

In FIG. 5, patterns may not be formed in the fourth die area 124. Instead, alignment marks 124AM may be disposed in the fourth die area 124. The alignment mark 124AM may be a mark that the measurement apparatus uses as a reference when imaging the die areas 120. In other words, the fourth die area 124 may be used as a reference for evaluating the imaging accuracy of the measurement apparatus. For example, the measurement apparatus may use the alignment mark 124AM in the fourth die area 124 to align itself to measure the patterns disposed in the first to third die areas 121, 122, and 123.

In one example, coordinates of the alignment mark 124AM formed at a center of the fourth die area 124 may be set to (0,0). An imaging unit of the measurement apparatus may be aligned based on the alignment mark 124AM at the center of the fourth die area 124.

In this way, the pattern measurement target 100 may include the plurality of die areas 120, and the plurality of patterns may be formed on each of the die areas 120. The plurality of patterns may have different sizes and different brightnesses.

According to some embodiments of the present disclosure, a pattern measurement method of the present disclosure may be used to measure a difference between the actual size and the measured size of the patterns and the difference between the actual brightness and the measured brightness thereof, and thus may be applied to a pattern measurement apparatus. Accordingly, the pattern measurement apparatus with improved precision may be provided.

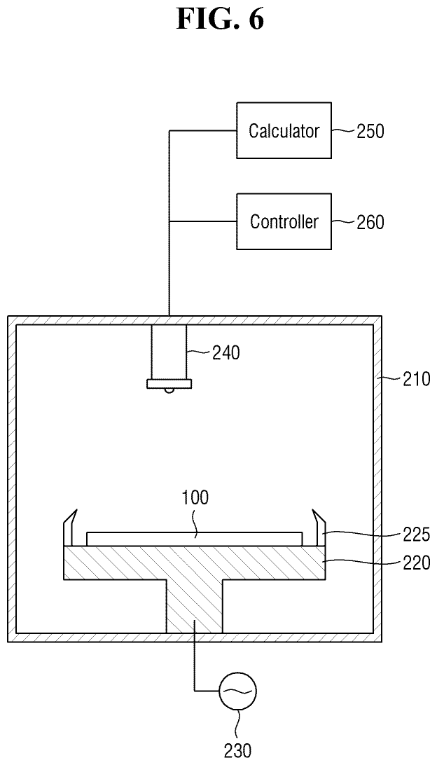

FIG. 6 is an example diagram for illustrating a measurement apparatus according to some embodiments of the present disclosure.

Referring to FIG. 6, the measurement apparatus according to some embodiments may include a housing 210, a stage 220, an imaging unit 240 (e.g., a camera), a calculator 250, and a controller 260.

The housing 210 may have an inner space defined therein where the measurement process is performed. The inner space may be sealed from an outside. An overall outer structure of the housing 210 may have a shape of a cylinder, an elliptical column, or a polygonal column. The housing 210 may be generally made of a metal material, and may be maintained in an electrical ground state to block noise from the outside during a plasma process.

In some embodiments, the stage 220 may be installed in the inner space of the housing 210. The stage 220 may be disposed under a treatment area. The stage 220 may support the pattern measurement target 100 thereon.

The stage 220 may include an electrostatic chuck configured to support the pattern measurement target 100 using an electro-static force, and a chuck support supporting the electrostatic chuck thereon. The electrostatic chuck may include therein electrodes for chucking and dechucking the pattern measurement target 100. The chuck support may support the electrostatic chuck disposed on a top surface thereof, and may be made of a metal such as aluminum or a ceramic insulator such as alumina. A heating member such as a heater may be disposed inside the chuck support, and heat from the heater may be transferred to the electrostatic chuck or the pattern measurement target 100. Moreover, a power application wiring connected to the electrode of the electrostatic chuck may be disposed in the chuck support. In another example, a configuration of the stage 220 is not limited thereto, and the stage 220 may include a vacuum chuck configured to support the pattern measurement target 100 using a vacuum, or may be configured to mechanically support the pattern measurement target 100 thereon.

The stage 220 may include a lift pin. The lift pin may be configured to lift the pattern measurement target 100 from the top surface of the stage 220 on which the pattern measurement target 100 has been mounted. The lift pin may be accommodated in a hole provided in the stage 220. The lift pin may be installed to be movable in a direction perpendicular to an upper surface of the pattern measurement target 100. The lift pin may move in a vertical direction to raise and lower the pattern measurement target 100. The stage 220 may include a suitable number of lift pins to support the pattern measurement target 100. For example, the stage 220 may include three or more lift pins evenly spaced from each other along a circumferential direction of the pattern measurement target 100. However, the present disclosure is not limited thereto.

When the pattern measurement target 100 to be treated is brought into the housing 210 or the pattern measurement target 100 as treated is taken out of the housing 210, the lift pin may be brought into a pin-up state in which the lift pin protrudes upwardly beyond the top surface the stage 220, and thus may support the pattern measurement target 100 thereon. Moreover, while the pattern measurement target 100 is being treated within the housing 210, the lift pin may be brought into in a pin-down state in which the lift pin is lowered downwardly beyond the top surface of the stage 220, such that the pattern measurement target 100 may be seated on the stage 220.

An RF (radio frequency) bias source 230 may be connected to the stage 220. The RF bias source 230 may apply RF power to the pattern measurement target 100.

In some embodiments, the stage 220 may further include a rim 225. The rim 225 may be provided on the stage 220. The rim 225 may surround the pattern measurement target 100 disposed on the stage 220. The rim 225 may prevent the pattern measurement target 100 from slipping on the stage 220. The rim 225 may include a ceramic material.

The imaging unit 240 may be installed on top of the stage 220. The imaging unit 240 may be installed on top of the pattern measurement target 100. The imaging unit 240 may be spaced apart from the pattern measurement target 100 in the vertical direction.

The imaging unit 240 may image the pattern measurement target 100. The imaging unit 240 may image the patterns formed on the pattern measurement target 100. Although not shown, light may be radiated to the pattern measurement target 100, and the imaging unit 240 may convert light reflected from a surface of the pattern measurement target 100 into data.

In some embodiments, the measured size and the measured brightness obtained by the imaging unit 240 by measuring the patterns formed on the pattern measurement target 100 may be different from the actual size and actual brightness of the patterns, respectively.

The calculator 250 may be connected to the imaging unit 240. The calculator 250 may calculate data acquired by the imaging unit 240. The data acquired by the imaging unit 240 may be, for example, the measured size of the patterns and the measured brightness of the patterns.

The controller 260 may control the calculator 250 and the imaging unit 240. The controller 260 may be a computing device such as a workstation computer, a desktop computer, a laptop computer, or a tablet computer. The controller may be embodied as a processor, microprocessor, CPU (Central Processing Unit), or firmware. The controller may be implemented, for example, by a general-purpose computer or specific hardware such as a DSP (Digital Signal Processor), FPGA (Field Programmable Gate Array), and ASIC (Application Specific Integrated Circuit). In one or more embodiments, some or all of the functions of the calculator 250 may be performed by the controller 260 or by a processor included in the controller 260.

An operation of the controller 260 may be implemented based on instructions stored in a machine-readable medium that may be read and executed by one or more processors. In this regard, the machine-readable medium may include any mechanism for storing and/or transmitting information in a form readable by a machine (e.g., a computing device). For example, the machine-readable medium may include read only memory (ROM), random access memory (RAM), magnetic disk storage media, optical storage media, and flash memory devices.

Although not illustrated, the calculator 250 and the controller 260 may together or independently include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the calculator 250 and/or controller 260 (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the calculator 250 and/or controller 260 can include antennas, network interfaces that provide wireless and/or wire line digital and/or analog interface to one or more networks over one or more network connections (not shown), a power source that provides an appropriate alternating current (AC) or direct current (DC) to power one or more components of the calculator 250 and/or controller 260, and a bus that allows communication among the various disclosed components of the calculator 250 and/or controller 260.

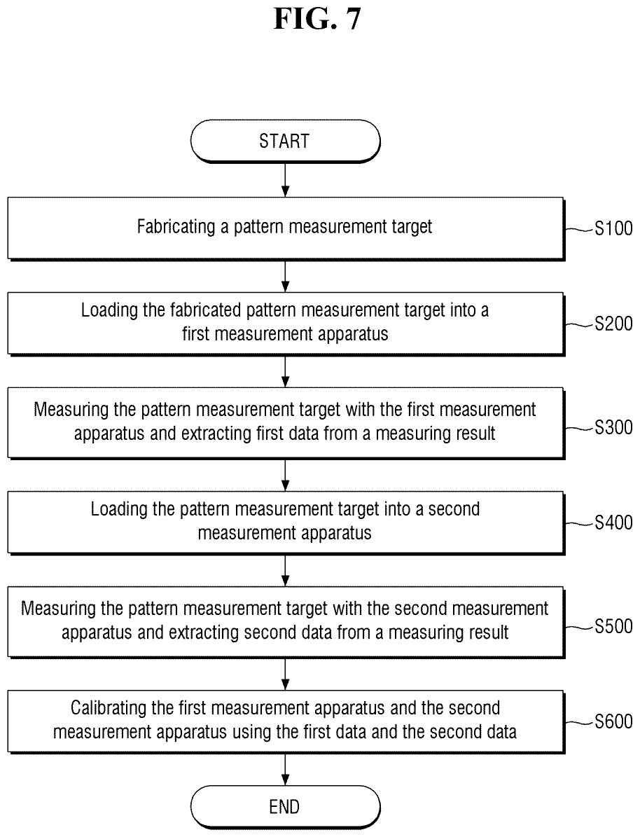

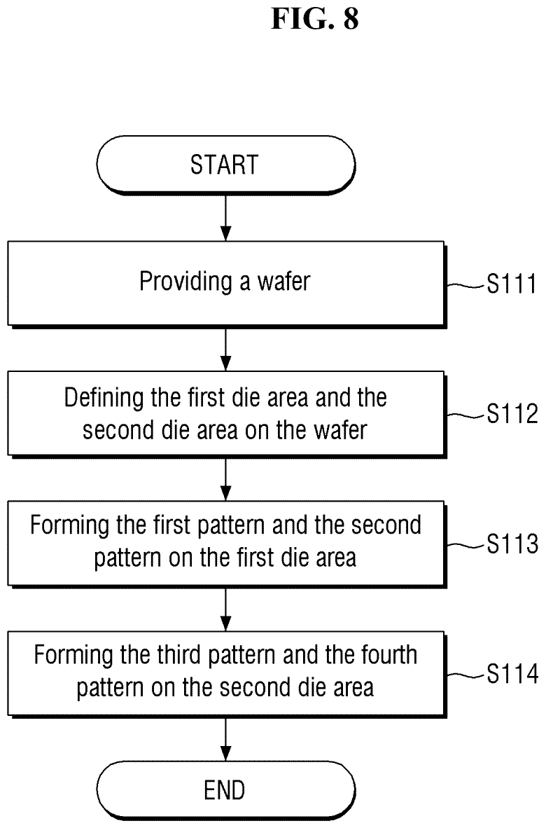

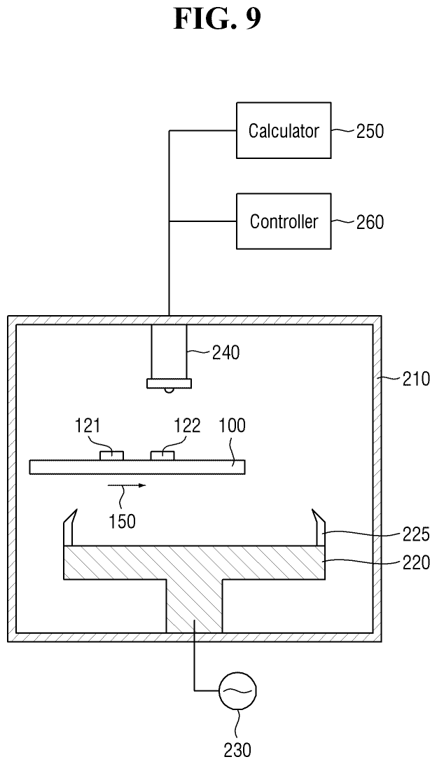

FIG. 7 is an example flow chart for illustrating a pattern measurement method according to some embodiments of the present disclosure. FIG. 8 is an example flowchart for illustrating a method for manufacturing the pattern measurement target in FIG. 7. FIGS. 9 to 12 are diagrams of intermediate structures corresponding to intermediate steps of the pattern measurement method according to some embodiments of the present disclosure.

First, referring to FIG. 7, the pattern measurement method according to some embodiments may include fabricating a pattern measurement target in S100, loading the fabricated pattern measurement target into a first measurement apparatus in S200, measuring the pattern measurement target with the first measurement apparatus and extracting first data from a measuring result in S300, loading the pattern measurement target into a second measurement apparatus in S400, measuring the pattern measurement target with the second measurement apparatus and extracting second data from a measuring result in S500, and calibrating the first measurement apparatus and the second measurement apparatus using the first data and the second data in S600.

Each of the first data and the second data may include the measured size and the measured brightness of the patterns formed on the pattern measurement target, size error data and brightness error data, or size correction data and brightness correction data.

Moreover, referring to FIG. 8, fabricating the pattern measurement target in S100 may include providing a wafer in S111, defining the first die area and the second die area on the wafer in S112, forming the first pattern and the second pattern on the first die area in S113, and forming the third pattern and the fourth pattern on the second die area in S114.

Specifically, first, referring to FIG. 8 and FIG. 1, a wafer 110 is provided in S111. The wafer 110 may be a silicon wafer. The plurality of die areas 120 may be defined on the wafer 110 in S112. Specifically, the first to fourth die areas 121, 122, 123, and 124 may be defined.

Next, referring to FIG. 8 and FIG. 2, the first pattern 121a and the second pattern 121b may be formed on the first die area 121 in S113. As described previously, the first pattern 121a and the second pattern 121b may have the same size and different brightnesses.

Subsequently, referring to FIG. 8 and FIG. 3, the third pattern 122a and the fourth pattern 122b may be formed on the second die area 122 in S114. As previously described, the third pattern 122a and the fourth pattern 122b may have the same size and different brightnesses. In this regard, the size of the first pattern 121a may be smaller than the size of the third pattern 122a.

Subsequently, the method may further include forming the patterns on each of the die areas.

Referring to FIG. 7 and FIG. 9, the fabricated pattern measurement target 100 may be loaded into the first measurement apparatus in S200. The pattern measurement target 100 may include the first die area 121 and the second die area 122. The pattern measurement target 100 may be loaded on the stage 220, for example, in direction 150 as shown in FIG. 9.

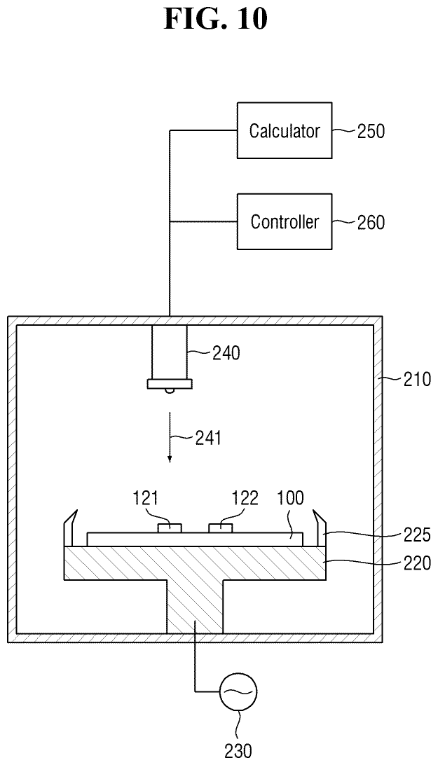

Referring to FIG. 7 and FIG. 10, the imaging unit 240 may image the first die area 121 of the pattern measurement target 100, for example, by emitting light in the direction 241. The imaging unit 240 may measure the first size and first brightness of the first pattern 121a formed on the first die area 121. Moreover, the imaging unit 240 may measure the second size and the second brightness of the second pattern 121b.

The imaging unit 240 may obtain a (1-1)-th measured size by imaging the first size of the first pattern 121a formed on the first die area 121. The imaging unit 240 may obtain a (1-1)-th measured brightness by imaging the first brightness of the first pattern 121a formed on the first die area 121.

The (1-1)-th measured size may be equal to or different from the actual size of the first pattern 121a. Likewise, the (1-1)-th measured brightness may be equal to or different from the actual brightness of the first pattern 121a.

The imaging unit 240 may obtain a (1-2)-th measured size by imaging the second size of the second pattern 121b formed on the first die area 121. The imaging unit 240 may acquire a (1-2)-th measured brightness by imaging the first brightness of the second pattern 121b formed on the first die area 121.

The (1-2)-th measured size may be equal to or different from the actual size of the second pattern 121b. Likewise, the (1-2)-th measured brightness may be equal to or different from the actual brightness of the second pattern 121b.

In some embodiments, the (1-1)-th measured size may be smaller than the (1-2)-th measured size. This may be because the first background 121c is darker than the second background 121d.

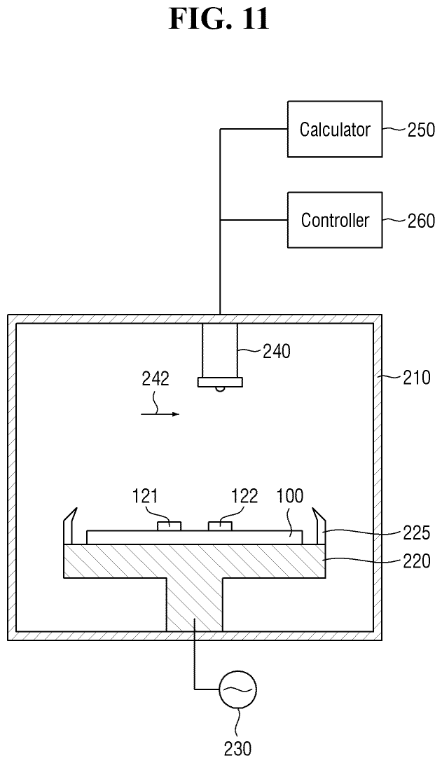

Referring to FIG. 11, the imaging unit 240 may move onto the second die area 122, for example, by moving in direction 242.

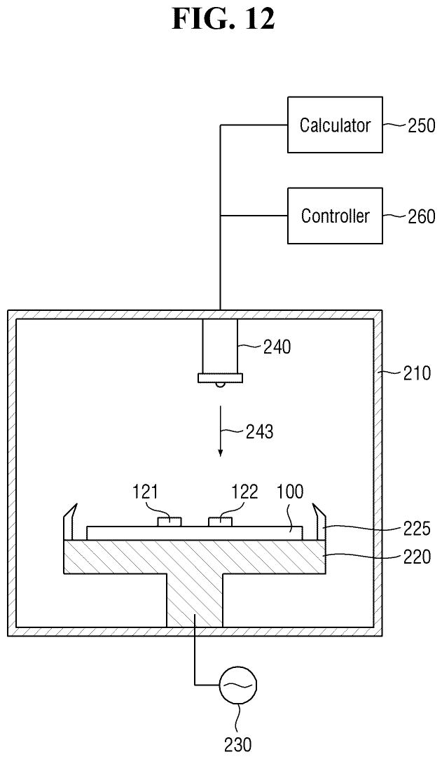

Referring to FIG. 12, the imaging unit 240 may image the second die area 122 of the pattern measurement target 100, for example, by emitting light in direction 243. The imaging unit 240 may measure the third size and the third brightness of the third pattern 122a formed on the second die area 122. Moreover, the imaging unit 240 may measure the fourth size and the fourth brightness of the fourth pattern 122b.

The imaging unit 240 may obtain a (1-3)-th measured size by imaging the third size of the third pattern 122a formed on the second die area 122. The imaging unit 240 may acquire a (1-3)-th measured brightness by imaging the third brightness of the third pattern 122a formed on the second die area 122.

The imaging unit 240 may obtain a (1-4)-th measured size by imaging the fourth size of the fourth pattern 122b formed on the second die area 122. The imaging unit 240 may obtain a (1-4)-th measured brightness by imaging the fourth brightness of the fourth pattern 122b formed on the second die area 122.

Although not shown, the imaging unit 240 may image a size and a brightness of patterns formed on another die area.

The calculator 250 may calculate (e.g., determine) a difference (e.g., a first difference) between the first size of the first pattern 121a and the (1-1)-th measured size obtained by the imaging unit 240 by imaging the first pattern 121a. In this regard, the first size of the first pattern 121a may be the actual size (e.g., a predetermined first size) of the first pattern 121a. The actual size of the first pattern 121a and the (1-1)-th measured size of the first pattern 121a imaged by the imaging unit 240 may be different from each other. The calculator 250 may define the difference between the first size and the (1-1)-th measured size as (1-1)-th size error data.

The calculator 250 may calculate a difference (e.g., a second difference) between the first brightness of the first pattern 121a and the (1-1)-th measured brightness obtained by the imaging unit 240 by imaging the first pattern 121a. In this regard, the first brightness of the first pattern 121a may be the actual brightness (e.g., a predetermined first brightness) of the first pattern 121a. The actual brightness of the first pattern 121a and the (1-1)-th measured brightness of the first pattern 121a imaged by the imaging unit 240 may be different from each other. The calculator 250 may define the difference between the first brightness and the (1-1)-th measured brightness as (1-1)-th brightness error data.

The calculator 250 may calculate a difference (e.g., a third difference) between the second size of the second pattern 121b and the (1-2)-th measured size obtained by the imaging unit 240 by imaging the second pattern 121b. In this regard, the second size of the second pattern 121b may be the actual size (e.g., a predetermined second size) of the second pattern 121b. The actual size of the second pattern 121b and the (1-2)-th measured size of the second pattern 121b imaged by the imaging unit 240 may be different from each other. The calculator 250 may define the difference between the second size and the (1-2)-th measured size as (1-2)-th size error data.

The calculator 250 may calculate a difference (e.g., a fourth difference) between the second brightness of the second pattern 121b and the (1-2)-th measured brightness obtained by the imaging unit 240 by imaging the second pattern 121b. In this regard, the second brightness of the second pattern 121b may be the actual brightness (e.g., a predetermined second brightness) of the second pattern 121b. The actual brightness of the second pattern 121b and the (1-2)-th measured brightness of the second pattern 121b imaged by the imaging unit 240 may be different from each other. The calculator 250 may define the difference between the second brightness and the (1-2)-th measured brightness as (1-2)-th brightness error data.

The calculator 250 may calculate a difference (e.g., a fifth difference) between the third size of the third pattern 122a and the (1-3)-th measured size obtained by the imaging unit 240 by imaging the third pattern 122a. In this regard, the third size of the third pattern 122a may be the actual size (e.g., a predetermined third size) of the third pattern 122a. The actual size of the third pattern 122a and the (1-3)-th measured size of the third pattern 122a imaged by the imaging unit 240 may be different from each other. The calculator 250 may define the difference between the third size and the (1-3)-th measured size as (1-3)-th size error data.

The calculator 250 may calculate a difference (e.g., a sixth difference) between the first brightness of the third pattern 122a and the (1-3)-th measured brightness obtained by the imaging unit 240 by imaging the third pattern 122a. In this regard, the first brightness of the third pattern 122a may be the actual brightness (e.g., a predetermined third brightness) of the third pattern 122a. The actual brightness of the third pattern 122a and the (1-3)-th measured brightness of the third pattern 122a imaged by the imaging unit 240 may be different from each other. The calculator 250 may define the difference between the third brightness and the (1-3)-th measured brightness as (1-3)-th brightness error data.

The calculator 250 may calculate a difference (e.g., a seventh difference) between the fourth size of the fourth pattern 122b and the (1-4)-th measured size obtained by imaging the fourth pattern 122b by the imaging unit 240. In this regard, the fourth size of the fourth pattern 122b may be the actual size (e.g., a predetermined fourth size) of the fourth pattern 122b. The actual size of the fourth pattern 122b and the (1-4)-th measured size of the fourth pattern 122b imaged by the imaging unit 240 may be different from each other. The calculator 250 may define the difference between the fourth size and the (1-4)-th measured size as (1-4)-th size error data.

The calculator 250 may calculate a difference (e.g., an eighth difference) between the fourth brightness of the fourth pattern 122b and the (1-4)-th measured brightness obtained by imaging the fourth pattern 122b by the imaging unit 240. In this regard, the fourth brightness of the fourth pattern 122b may be the actual brightness (e.g., a predetermined fourth brightness) of the fourth pattern 122b. The actual brightness of the fourth pattern 122b and the (1-4)-th measured brightness of the fourth pattern 122b imaged by the imaging unit 240 may be different from each other. The calculator 250 may define the difference between the fourth brightness and the (1-4)-th measured brightness as (1-4)-th brightness error data.

The (1-1)-th size error data, the (1-1)-th brightness error data, the (1-2)-th size error data, the (1-2)-th brightness error data, the (1-3)-th size error data, the (1-3)-th brightness error data, the (1-4)-th size error data, and the (1-4)-th brightness error data may be included in the first data. The first data may be extracted from the measuring result of the pattern measurement target with the first measurement apparatus.

In this regard, the first size of the first pattern 121a may be equal to the second size of the second pattern 121b. However, the first size of the first pattern 121a may be smaller than the third size of the third pattern 122a. The third size of the third pattern 122a may be equal to the fourth size of the fourth pattern 122b.

Subsequently, referring to FIG. 7, the pattern measurement target 100 may be loaded into the second measurement apparatus which is different from the first measurement apparatus in S400. Within the second measurement apparatus, the size and the brightness of the first to fourth patterns 121a, 121b, 122a, and 122b formed on the pattern measurement target 100 may be imaged.

In the same way as described above with reference to the first measurement apparatus, the calculator of the second measurement apparatus may calculate (2-1)-th size error data, (2-1)-th brightness error data, (2-2)-th size error data, (2-2)-th brightness error data, (2-3)-th size error data, (2-3)-th brightness error data, (2-4)-th size error data, and (2-4)-th brightness error data.

Specifically, the imaging unit of the second measurement apparatus may obtain a (2-1)-th measured size and a (2-1)-th measured brightness by imaging the first pattern 121a. The imaging unit of the second measurement apparatus may obtain a (2-2)-th measured size and a (2-2)-th measured brightness by imaging the second pattern 121b. The imaging unit of the second measurement apparatus may obtain a (2-3)-th measured size and a (2-3)-th measured brightness by imaging the third pattern 122a. Finally, the imaging unit of the second measurement apparatus may obtain a (2-4)-th measured size and a (2-4)-th measured brightness by imaging the fourth pattern 122b.

The calculator of the second measurement apparatus may calculate a difference between the first size of the first pattern 121a and the (2-1)-th measured size. In this regard, the first size of the first pattern 121a may be the actual size of the first pattern 121a. The actual size of the first pattern 121a and the (2-1)-th measured size may be different from each other. The calculator of the second measurement apparatus may define the difference between the first size and the (2-1)-th measured size as the (2-1)-th size error data.

The calculator of the second measurement apparatus may calculate a difference between the first brightness of the first pattern 121a and the (2-1)-th measured brightness. In this regard, the first brightness of the first pattern 121a may be the actual brightness of the first pattern 121a. The actual brightness of the first pattern 121a and the (2-1)-th measured brightness of the first pattern 121a may be different from each other. The calculator of the second measurement apparatus may define the difference between the first brightness and the (2-1)-th measured brightness as the (2-1)-th brightness error data.

The calculator of the second measurement apparatus may calculate a difference between the second size of the second pattern 121b and the (2-2)-th measured size. In this regard, the second size of the second pattern 121b may be the actual size of the second pattern 121b. The actual size of the second pattern 121b and the (2-2)-th measured size may be different from each other. The calculator of the second measurement apparatus may define the difference between the second size and the (2-2)-th measured size as the (2-2)-th size error data.

The calculator of the second measurement apparatus may calculate a difference between the second brightness of the second pattern 121b and the (2-2)-th measured brightness. In this regard, the second brightness of the second pattern 121b may be the actual brightness of the second pattern 121b. The actual brightness of the second pattern 121b and the (2-2)-th measured brightness of the second pattern 121b may be different from each other. The calculator of the second measurement apparatus may define the difference between the second brightness and the (2-2)-th measured brightness as the (2-2)-th brightness error data.

The calculator of the second measurement apparatus may calculate a difference between the third size of the third pattern 122a and the (2-3)-th measured size. In this regard, the third size of the third pattern 122a may be the actual size of the third pattern 122a. The actual size of the third pattern 122a and the (2-3)-th measured size may be different from each other. The calculator of the second measurement apparatus may define the difference between the third size and the (2-3)-th measured size as the (2-3)-th size error data.

The calculator of the second measurement apparatus may calculate a difference between the third brightness of the third pattern 122a and the (2-3)-th measured brightness. In this regard, the third brightness of the third pattern 122a may be the actual brightness of the third pattern 122a. The actual brightness of the third pattern 122a and the (2-3)-th measured brightness of the third pattern 122a may be different from each other. The calculator of the second measurement apparatus may define the difference between the third brightness and the (2-3)-th measured brightness as the (2-3)-th brightness error data.

The calculator of the second measurement apparatus may calculate a difference between the fourth size of the fourth pattern 122b and the (2-4)-th measured size. In this regard, the fourth size of the fourth pattern 122b may be the actual size of the fourth pattern 122b. The actual size of the fourth pattern 122b and the (2-4)-th measured size may be different from each other. The calculator of the second measurement apparatus may define the difference between the fourth size and the (2-4)-th measured size as the (2-4)-th size error data.

The calculator of the second measurement apparatus may calculate a difference between the fourth brightness of the fourth pattern 122b and the (2-4)-th measured brightness. In this regard, the fourth brightness of the fourth pattern 122b may be the actual brightness of the fourth pattern 122b. The actual brightness of the fourth pattern 122b and the (2-4)-th measured brightness of the fourth pattern 122b may be different from each other. The calculator of the second measurement apparatus may define the difference between the fourth brightness and the (2-4)-th measured brightness as the (2-4)-th brightness error data.

The (2-1)-th size error data, the (2-1)-th brightness error data, the (2-2)-th size error data, the (2-2)-th brightness error data, the (2-3)-th size error data, the (2-3)-th brightness error data, the (2-4)-th size error data, and the (2-4)-th brightness error data may be included in the second data.

The second data may be extracted from a measuring result of the pattern measurement target with the second measurement apparatus in S500.

The first measurement apparatus and the second measurement apparatus may be calibrated using the first data and the second data.

First size correction data may be generated as an average of the (1-1)-th size error data and the (1-2)-th size error data. For example, it is assumed that the first size is 100. In this regard, when imaging the first pattern 121a with the first measurement apparatus, the (1-1)-th measured size may be 90. When imaging the first pattern 121a with the second measurement apparatus, the (2-1)-th measured size may be 105. In this case, the (1-1)-th size error data may be −10, and the (2-1)-th size error data may be +5. The first size correction data may be −2.5.

First brightness correction data may be generated as an average of the (1-1)-th brightness error data and the (1-2)-th brightness error data. For example, it is assumed that the first brightness is 200. In this regard, when imaging the first pattern 121a with the first measurement apparatus, the (1-1)-th measured brightness may be 195. When imaging the first pattern 121a with the second measurement apparatus, the (2-1)-th measured brightness may be 210. In this case, the (1-1)-th brightness error data may be −5, and the (2-1)-th brightness error data may be +10. The first brightness correction data may be +2.5.

The first size correction data and the first brightness correction data may be applied to the first measurement apparatus and the second measurement apparatus.

The wafer may be transported to multiple apparatuses. For example, the wafer may be loaded from the first measurement apparatus to the second measurement apparatus. In this process, the wafer alignment process is essential. The first size correction data and the first brightness correction data may be applied to the first measurement apparatus, and wafer alignment correction may be performed. Additionally, the first size data and the first brightness correction data may be applied to the second measurement apparatus, and wafer alignment correction may be performed.

Likewise, the difference between the second size and the (1-2)-th measured size may be defined as the (1-2)-th size error data. The difference between the second size and the (2-2)-th measured size may be defined as the (2-2)-th size error data. The difference between the intensity of the second brightness and the intensity of the (1-2)-th measured brightness may be defined as the (1-2)-th brightness error data. The difference between the intensity of the second brightness and the intensity of the (2-2)-th brightness may be defined as the (2-2)-th brightness error data.

Second size correction data may be generated as an average of the (1-2)-th size error data and the (2-2)-th size error data. Second brightness correction data may be generated as an average of the (1-2)-th brightness error data and the (2-2)-th brightness error data. The second size correction data and the second brightness correction data may be applied to the first measurement apparatus and the second measurement apparatus.

In this way, the pattern measurement target may be imaged to simultaneously obtain the sizes and the brightnesses of the patterns which in turn may be compared with each other using the method according to some embodiments. Accordingly, the pattern measurement method with improved accuracy may be provided.

Although embodiments of the present disclosure have been described with reference to the accompanying drawings, embodiments of the present disclosure are not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A pattern measurement method comprising:
defining a first die area and a second die area on a wafer;
forming a first pattern having a predetermined first size and a predetermined first brightness in the first die area;
forming a second pattern having a predetermined second size equal to the predetermined first size and a predetermined second brightness different from the predetermined first brightness in the first die area;
measuring the predetermined first size and the predetermined first brightness of the first pattern using a first measurement apparatus and obtaining a (1-1)-th measured size and a (1-1)-th measured brightness, respectively, from a measuring result using the first measurement apparatus, and measuring the predetermined second size and the predetermined second brightness of the second pattern using the first measurement apparatus and obtaining a (1-2)-th measured size and a (1-2)-th measured brightness, respectively, from a measuring result using the first measurement apparatus;
measuring the predetermined first size and the predetermined first brightness of the first pattern using a second measurement apparatus different from the first measurement apparatus, and obtaining a (2-1)-th measured size and a (2-1)-th measured brightness, respectively, from a measuring result using the second measurement apparatus, and measuring the predetermined second size and the predetermined second brightness of the second pattern using the second measurement apparatus and obtaining a (2-2)-th measured size and a (2-2)-th measured brightness, respectively, from a measuring result using the second measurement apparatus;
defining a difference between the predetermined first size and the (1-1)-th measured size as (1-1)-th size error data;
defining a difference between the predetermined first size and the (2-1)-th measured size as (2-1)-th size error data;
defining a difference between an intensity of the predetermined first brightness and an intensity of the (1-1)-th measured brightness as (1-1)-th brightness error data;
defining a difference between the intensity of the predetermined first brightness and an intensity of the (2-1)-th measured brightness as (2-1)-th brightness error data,
generating first size correction data as an average of the (1-1)-th size error data and the (2-1)-th size error data;
generating first brightness correction data as an average of the (1-1)-th brightness error data and the (2-1)-th brightness error data; and
calibrating the first measurement apparatus and the second measurement apparatus based on the first size correction data and the first brightness correction data.

2. The pattern measurement method of claim 1, wherein the method further comprises:
defining a difference between the predetermined second size and the (1-2)-th measured size as (1-2)-th size error data;
defining a difference between the predetermined second size and the (2-2)-th measured size as (2-2)-th size error data;
defining a difference between an intensity of the predetermined second brightness and an intensity of the (1-2)-th measured brightness as (1-2)-th brightness error data;
defining a difference between the intensity of the predetermined second brightness and an intensity of the (2-2)-th measured brightness as (2-2)-th brightness error data;
generating second size correction data as an average of the (1-2)-th size error data and the (2-2)-th size error data;
generating second brightness correction data as an average of the (1-2)-th brightness error data and the (2-2)-th brightness error data; and
calibrating the first measurement apparatus and the second measurement apparatus based on the second size correction data and the second brightness correction data.

3. The pattern measurement method of claim 1, further comprising:
forming a third pattern having a predetermined third size different from the predetermined first size and a predetermined third brightness different from each of the predetermined first and second brightnesses in the second die area;
forming a fourth pattern having a predetermined fourth size equal to the predetermined third size and a predetermined fourth brightness different from each of the predetermined first to third brightnesses in the second die area;
measuring the predetermined third size and the predetermined third brightness of the third pattern with the first measurement apparatus and obtaining a (1-3)-th measured size and a (1-3)-th measured brightness, respectively, from a measuring result using the first measurement apparatus, and measuring the predetermined fourth size and the predetermined fourth brightness of the fourth pattern with the first measurement apparatus and obtaining a (1-4)-th measured size and a (1-4)-th measured brightness, respectively, from a measuring result using the first measurement apparatus;
measuring the predetermined third size and the predetermined third brightness of the third pattern with the second measurement apparatus and obtaining a (2-3)-th measured size and a (2-3)-th measured brightness, respectively, from a measuring result using the second measurement apparatus, and measuring the predetermined fourth size and the predetermined fourth brightness of the fourth pattern with the second measurement apparatus and obtaining a (2-4)-th measured size and a (2-4)-th measured brightness, respectively, from a measuring result using the second measurement apparatus;
defining a difference between the predetermined third size and the (1-3)-th measured size as (1-3)-th size error data;
defining a difference between the predetermined third size and the (2-3)-th measured size as (2-3)-th size error data;
defining a difference between an intensity of the predetermined third brightness and an intensity of the (1-3)-th measured brightness as (1-3)-th brightness error data;
defining a difference between the intensity of the predetermined third brightness and an intensity of the (2-3)-th measured brightness as (2-3)-th brightness error data;
generating third size correction data as an average of the (1-3)-th size error data and the (2-3)-th size error data;
generating third brightness correction data as an average of the (1-3)-th brightness error data and the (2-3)-th brightness error data; and
calibrating the first measurement apparatus and the second measurement apparatus based on the third size correction data and the third brightness correction data.

4. The pattern measurement method of claim 3, further comprising:
defining a difference between the predetermined fourth size and the (1-4)-th measured size as (1-4)-th size error data;
defining a difference between the predetermined fourth size and the (2-4)-th measured size as (2-4)-th size error data;
defining a difference between an intensity of the predetermined fourth brightness and an intensity of the (1-4)-th measured brightness as (1-4)-th brightness error data;
defining a difference between the intensity of the predetermined fourth brightness and an intensity of the (2-4)-th measured brightness as (2-4)-th brightness error data;
generating fourth size correction data as an average of the (1-4)-th size error data and the (2-4)-th size error data;
generating fourth brightness correction data as an average of the (1-4)-th brightness error data and the (2-4)-th brightness error data; and
calibrating the first measurement apparatus and the second measurement apparatus based on the fourth size correction data and the fourth brightness correction data.

5. The pattern measurement method of claim 1, wherein the (1-1)-th measured size is smaller than the (1-2)-th measured size.

6. The pattern measurement method of claim 1, wherein the intensity of the predetermined first brightness is greater than the intensity of the predetermined second brightness,
wherein a brightness of a background of the first pattern is lower than a brightness of a background of the second pattern.

7. The pattern measurement method of claim 1, wherein the intensity of each of the predetermined first and second brightnesses is expressed as a number in a range from 0 to 255, and
wherein the intensity of the predetermined first brightness is in a range from 0 to 125 and the intensity of the predetermined second brightness is in a range from 126 to 255.

8. The pattern measurement method of claim 1, wherein each of the first and second measurement apparatuses includes an imaging unit configured to image the first and second patterns.

9. The pattern measurement method of claim 1, further comprising defining a third die area where a pattern is not formed on the wafer,
wherein the method further comprises using the third die area as a reference to evaluate measurement accuracy of each of the first and second measurement apparatuses.

10. The pattern measurement method of claim 9, wherein a coordinate of the third die area is defined as (0,0), and
the method further comprises detecting an alignment mark formed at the coordinate (0,0) of the third die area.

11. A pattern measurement method comprising:
fabricating a pattern measurement target;
measuring the pattern measurement target using a first measurement apparatus, and measuring the pattern measurement target using a second measurement apparatus different from the first measurement apparatus, and generating size correction data and brightness correction data based on a measuring result using the first measurement apparatus, and based on a measuring result using the second measurement apparatus; and
calibrating the first measurement apparatus and the second measurement apparatus based on the size correction data and the brightness correction data,
wherein the fabricating the pattern measurement target includes:
defining a first die area, a second die area, and a third die area on a wafer;
forming a first pattern group including a first pattern and a second pattern in the first die area, wherein the first pattern has a predetermined first size and a predetermined first brightness, and the second pattern has a predetermined second size equal to the predetermined first size and a predetermined second brightness different from the predetermined first brightness;
forming a second pattern group including a third pattern and a fourth pattern in the second die area, wherein the third pattern has a predetermined third size different from the predetermined first size and a predetermined third brightness and the fourth pattern has a predetermined fourth size equal to the predetermined third size, and a predetermined fourth brightness different from the predetermined third brightness; and
forming a third pattern group including a fifth pattern and a sixth pattern in the third die area, wherein the fifth pattern has a predetermined fifth size different from each of the predetermined first and third sizes, and a predetermined fifth brightness, and the sixth pattern has a predetermined sixth size equal to the predetermined fifth size, and a predetermined sixth brightness different from the predetermined fifth brightness,
wherein the measuring the pattern measurement target using the first measurement apparatus includes measuring a size and a brightness of each of the patterns of each of the first to third pattern groups using the first measurement apparatus,
wherein the measuring the pattern measurement target using the second measurement apparatus includes measuring a size and a brightness of each of the patterns of each of the first to third pattern groups using the second measurement apparatus,
wherein the size correction data is generated based on a difference between the measured size of each of the patterns of each of the first to third pattern groups and the predetermined size of each of the patterns of each of the first to third pattern groups, and
wherein the brightness correction data is generated based on a difference between the measured brightness of each of the patterns of each of the first to third pattern groups and the predetermined brightness of each of the patterns of each of the first to third pattern groups.

12. The pattern measurement method of claim 11, further comprising:
measuring the predetermined first size and the predetermined first brightness of the first pattern using the first measurement apparatus and obtaining a (1-1)-th measured size and a (1-1)-th measured brightness from a measuring result using the first measurement apparatus, and measuring the predetermined second size and the predetermined second brightness of the second pattern using the first measurement apparatus and obtaining a (1-2)-th measured size and a (1-2)-th measured brightness from a measuring result using the first measurement apparatus;
measuring the predetermined first size and the predetermined first brightness of the first pattern using the second measurement apparatus different from the first measurement apparatus, and obtaining a (2-1)-th measured size and a (2-1)-th measured brightness from a measuring result using the second measurement apparatus, and measuring the predetermined second size and the predetermined second brightness of the second pattern using the second measurement apparatus and obtaining a (2-2)-th measured size and a (2-2)-th measured brightness from a measuring result using the second measurement apparatus;
defining a difference between the predetermined first size and the (1-1)-th measured size as (1-1)-th size error data;
defining a difference between the predetermined first size and the (2-1)-th measured size as (1-2)-th size error data;
defining a difference between an intensity of the predetermined first brightness and an intensity of the (1-1)-th measured brightness as (1-1)-th brightness error data;
defining a difference between the intensity of the predetermined first brightness and an intensity of the (2-1)-th measured brightness defined as (1-2)-th brightness error data,
generating first size correction data as an average of the (1-1)-th size error data and the (1-2)-th size error data; and
generating first brightness correction data as an average of the (1-1)-th brightness error data and the (1-2)-th brightness error data.

13. The pattern measurement method of claim 12, wherein the (1-1)-th measured size is smaller than the (1-2)-th measured size.

14. The pattern measurement method of claim 11, wherein the predetermined first size is smaller than the predetermined third size,
wherein a difference between an intensity of the predetermined first brightness and an intensity of the predetermined second brightness is smaller than a difference between an intensity of the predetermined third brightness and an intensity of the predetermined fourth brightness.

15. The pattern measurement method of claim 14, wherein the predetermined third size is smaller than the predetermined fifth size,
wherein the difference between the intensity of the predetermined third brightness and the intensity of the predetermined fourth brightness is smaller than a difference between an intensity of the predetermined fifth brightness and an intensity of the predetermined sixth brightness.

16. The pattern measurement method of claim 11, wherein an intensity of each of the predetermined first to sixth brightnesses is expressed as a number in a range of 0 to 255, and
wherein the intensity of the predetermined first brightness is in a range of 0 to 125 and the intensity of the predetermined second brightness is in a range of 126 to 255.

17. A pattern measurement apparatus comprising:
a stage onto which a pattern measurement target is loaded;
an imaging unit installed on top of the pattern measurement target and configured to image the pattern measurement target;
a controller configured to control the imaging unit,
wherein the pattern measurement target includes:
a wafer including a first die area and a second die area;
a first pattern on the first die area and having a predetermined first size and a predetermined first brightness; and
a second pattern on the first die area and having a predetermined second size equal to the predetermined first size, and a predetermined second brightness different from the predetermined first brightness,
wherein the imaging unit is configured to:
image the first pattern and acquire a first measured size and a first measured brightness of the first pattern; and
image the second pattern and acquire a second measured size and a second measured brightness of the second pattern,
wherein the controller is configured to:
determine a first difference between the predetermined first size and the first measured size;
determine a second difference between the predetermined second size and the second measured size;
determine a third difference between an intensity of the predetermined first brightness and an intensity of the first measured brightness; and
determine a fourth difference between an intensity of the predetermined second brightness and an intensity of the second measured brightness; and
calibrate the pattern measurement apparatus based on the determined first to fourth differences.

18. The pattern measurement apparatus of claim 17, wherein the pattern measurement target further includes:
a third pattern in the second die area and having a predetermined third size larger than the predetermined first size, and a predetermined third brightness different from each of the predetermined first and second brightnesses; and
a fourth pattern in the second die area and having a predetermined fourth size equal to the predetermined third size, and a predetermined fourth brightness different from each of the predetermined first to third brightnesses,
the imaging unit is further configured to:
image the third pattern and acquire a third measured size and a third measured brightness of the third pattern; and
image the fourth pattern and acquire a fourth measured size and a fourth measured brightness of the fourth pattern,
wherein the controller is configured to:
determine a fifth difference between the predetermined third size and the third measured size;
determine a sixth difference between the predetermined fourth size and the fourth measured size;
determine a seventh difference between an intensity of the predetermined third brightness and an intensity of the third measured brightness; and
determine a eighth difference between an intensity of the predetermined fourth brightness and an intensity of the fourth measured brightness; and
calibrate the pattern measurement apparatus based on the determined fifth to eighth differences.

19. The pattern measurement apparatus of claim 18, wherein the predetermined first size is smaller than the predetermined third size,
wherein a difference between the intensity of the predetermined first brightness and the intensity of the predetermined second brightness is smaller than a difference between the intensity of the predetermined third brightness and the intensity of the predetermined fourth brightness.

20. The pattern measurement apparatus of claim 18, wherein the intensity of each of the first to fourth brightnesses is expressed as a number in a range from 0 to 255, and
wherein the intensity of the predetermined first brightness is in a range from 0 to 125 and the intensity of the predetermined second brightness is in a range from 126 to 255.
